(19) United States
(12) Patent Application Publication
(10) Pub. No.: US 2009/0302397 A1
(43) Pub. Date: Dec. 10, 2009

(54) Field-Effect Transistor

(76) Inventors: Klaus Voigtlaender, Wangen (DE); Johannes Duerr, Reutlingen (DE); Uwe Wostradowski, Renningen (DE); Antoine Chabaud, Stuttgart-Stammheim (DE)

Correspondence Address: KENYON & KENYON LLP, ONE BROADWAY, NEW YORK, NY, 10004, US

(21) Appl. No.: 11/920,864

(22) PCT Filed: Apr. 5, 2006
(86) PCT No.: PCT/EP2006/061320

§ 371 Date: Jul. 16, 2009

(30) Foreign Application Priority Data
May 20, 2005 (DE) 10 2005 023 361.9

(51) Int. Cl. H01L 27/088; H01L 29/78

(52) U.S. Cl. 257/379; 257/368; 257/337; 257/E29.255; 257/E27.06

(57) ABSTRACT

A field-effect transistor, having a source electrode, a drain electrode and a gate electrode, which has a connection between the gate electrode and the source electrode or between the gate electrode and the drain electrode or between the gate electrode and the substrate which carries a leakage current.

### FIELD OF THE INVENTION

The present invention relates to a field-effect transistor which has a source electrode, a drain electrode and a gate electrode.

### BACKGROUND INFORMATION

It is known that one may use soldering points, adhesive connections and wire bonding connections as electrical contacting of a component to a circuit substrate or a component packaging, in connection with control units used in the motor vehicle field. This circuit substrate is, for instance, an organic printed-circuit board or a ceramic printed-circuit board.

It is also known that one may use MOS field-effect transistors in power output stages as switching elements, for instance in the case of fan motors.

The MOS field-effect transistors may be enhancement MOSFET's of the n-type or the p-type. Such MOSFET's have a source electrode, a drain electrode and a gate electrode. In the case of an enhancement MOSFET of the n-type, if a positive voltage is applied between the drain electrode and the source electrode, and also a positive voltage (gate voltage) of a specified magnitude between the gate electrode and the source electrode, the MOSFET becomes conductive. If the gate voltage falls below a specified value, the MOSFET blocks. This gate voltage for blocking the MOSFET must be specified from outside, since a MOSFET itself cannot discharge the electric field at the gate electrode. In other words, this means that the electric charges at the gate electrode in known MOSFET's cannot discharge to ground or source through the component itself. For this reason, it has been suggested to provide an external current path from the gate electrode to ground, that is implemented by using wire bonding connections, soldering points or adhesive connections. The charge that is present at the gate electrode can discharge via this external current path, so that the electrical field between the gate electrode and the source electrode or the gate electrode and the drain electrode is discharged, and the MOSFET blocks.

Now if, during operation, destruction occurs of the present wire bonding connections, soldering points or adhesive connections because of a thermal, thermomechanical or chemical stress, then the charge present at the gate electrode cannot discharge. This has the effect that the MOSFET remains in a conductive state in an undesired manner. As a result, there is overheating of electronic components that are situated in the drain-source current path of the MOSFET. This includes MOSFET's themselves as well as ohmic resistors and coils/chokes. If the MOSFET is used in connection with a control unit of a motor vehicle as a switching element in a power output stage, what can happen is a complete destruction and/or a fire in the control unit or even the entire motor vehicle, under certain circumstances.

### SUMMARY OF THE INVENTION

When a field-effect transistor according to the present invention is used, the disadvantages described above do not even occur in response to the destruction of the wire bonding connections, soldering points or cable connections, or faults in them. For, because of the connection on the MOSFET itself, which carries a leakage current, the gate electrode of the MOSFET can be discharged by a leakage current flowing between the gate and ground (=substrate or rather source or drain).

Compared to current integrated semiconductor power output stage circuits, this leakage current path has the advantage that the discharge of the gate electrode can be implemented in a simple manner. The leakage current path, which is a high-ohmic current path, has a comparatively large time constant, that is in the range of several seconds. Care has to be taken only that the time constant is dimensioned in such a way that the MOSFET switches off fast enough, in response to a destroyed external connection of the gate electrode to ground, so that overheating of the MOSFET itself or of additional components situated in the drain-source path is avoided.

All the power MOSFET's known up to now are furnished with far more complex peripheral circuits. These offer protection against overloading of the MOSFET, to be sure, but they are considerably more costly, and thus more cost-intensive. In addition, the known peripheral circuits offer no direct protection against a destroyed connection between gate electrode and ground, so that the gate electrode cannot be discharged.

### BRIEF DESCRIPTION OF THE DRAWINGS

FIG. 1 shows an MOS field-effect transistor according to a first specific embodiment of the present invention.

FIG. 2 shows an MOS field-effect transistor according to a second specific embodiment of the present invention.

FIG. 3 shows an MOS field-effect transistor according to a third specific embodiment of the present invention.

FIG. 4 shows a diagram to illustrate the doping of the p-type area shown in FIG. 3, as a function of the distance from the gate electrode.

### DETAILED DESCRIPTION

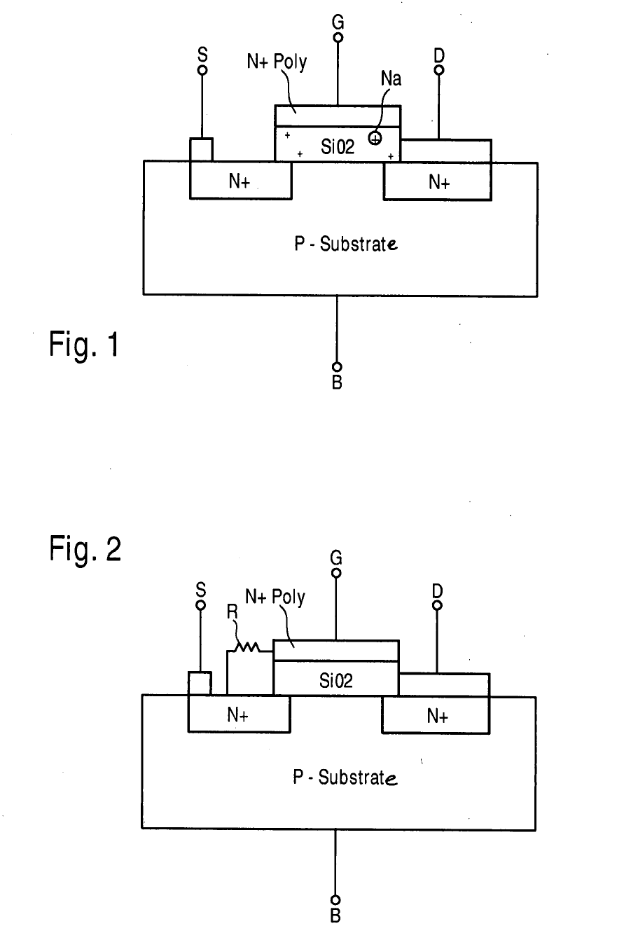

FIG. 1 shows an MOS field-effect transistor according to a first specific embodiment of the present invention. The MOS field-effect transistor shown is an enhancement MOS field-effect transistor of the n-type. It has a gate electrode G, a source electrode S and a drain electrode D. The gate connection is made up of aluminum and n+ polysilicon and is connected to the p-substrate via a silicon dioxide layer SiO₂. A fourth connection B of the MOS field-effect transistor is allocated to the p-substrate. In the present specific embodiment, this connection is not used for control purposes but is connected to source electrode S. In the p-substrate there are two n+ doped regions. One of these regions is connected to source electrode S. The other of these n+ doped regions is connected to drain electrode D.

According to this first specific embodiment of the present invention, ions or rather acceptor Na in weak doping are implanted into the silicon dioxide layer SiO₂, which form a high-ohmic current path between gate electrode G and ground or between gate electrode G and substrate S (=ground). A leakage current can flow over this current path by which gate electrode G can be discharged if the MOSFET is to be brought into the blocked state. This leakage current path is even maintained if, during operation, based on a thermal, thermomechanical or chemical stress, soldering points, wire bonding connections and adhesive connections have been damaged, which are supposed to produce electrical contact between the gate and the respectively present circuit substrate or the respectively present component packaging.

FIG. 2 shows an MOS field-effect transistor according to a second specific embodiment of the present invention. The MOS field-effect transistor shown in FIG. 2 is also an enhancement MOS field-effect transistor of the n-type. It has a gate electrode G, a source electrode S and a drain electrode D. Gate electrode G is made up of aluminum and n+ polysilicon and is connected to the p-substrate via a silicon dioxide layer SiO₂. A fourth connection B of the MOS field-effect transistor is allocated to the p-substrate. In the specific embodiment shown in FIG. 2, this is also not used for control purposes but is connected to source electrode S. In the p-substrate there are two n+ doped regions. One of these regions is connected to source electrode S. The other of these n+ doped regions is connected to drain electrode D.

According to the second specific embodiment of the present invention, gate electrode G is connected via an ohmic resistor R to one of the n+ doped regions, and thus to source electrode S. This ohmic resistor R forms a high-ohmic leakage current path between gate electrode G and source electrode S. A leakage current can flow via this current path by which gate electrode G can be discharged if the MOSFET is to be brought into the blocked state. This leakage current path is even maintained if, during operation, based on a thermal, thermomechanical or chemical stress, soldering points, wire bonding connections and adhesive connections have been damaged, which are supposed to produce electrical contact between the gate and the respectively present circuit substrate or the respectively present component packaging.

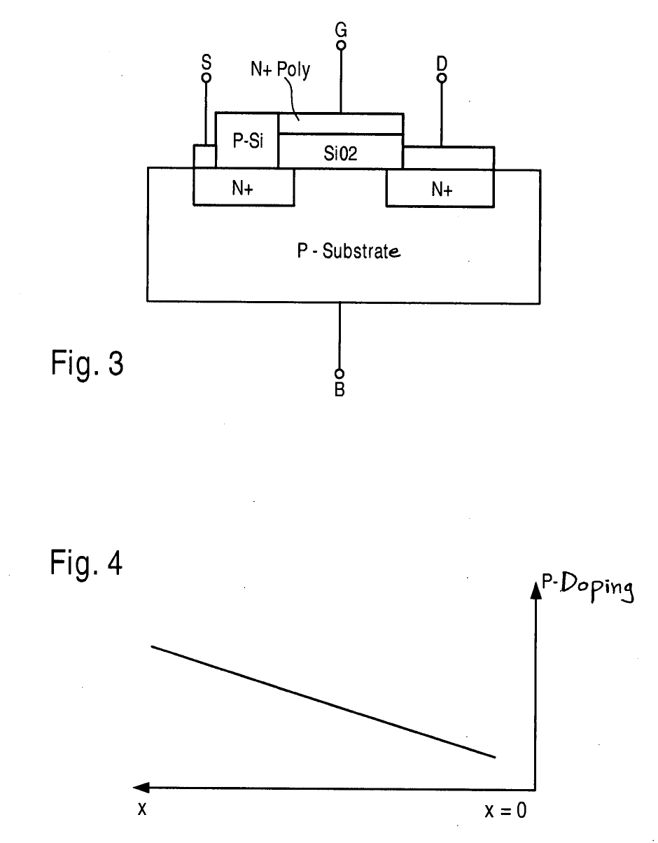

FIG. 3 shows an MOS field-effect transistor according to a third specific embodiment of the present invention. The MOS field-effect transistor shown in FIG. 3 is also an enhancement MOS field-effect transistor of the n-type. It has a gate electrode G, a source electrode S and a drain electrode D. Gate electrode G is made up of aluminum and n+ polysilicon and is connected to the p-substrate via a silicon dioxide layer SiO₂. A fourth connection B of the MOS field-effect transistor is allocated to the p-substrate. In the specific embodiment shown in FIG. 3, this is also not used for control purposes but is connected to source electrode S. In the p-substrate there are two n+ doped regions. One of these regions is connected to source electrode S. The other of these n+ doped regions is connected to drain electrode D. Furthermore, there is a p-silicon block between the gate and the n+ doped region connected to source electrode S.

This third specific embodiment implements a Schottky diode between gate electrode G and source electrode S. As was mentioned above, gate electrode G is made up of aluminum and n+ polysilicon. Since the work function of aluminum and n+ polysilicon is less than the work function of the p-silicon block that is provided between gate electrode G and source electrode S, the device shown manifests the effect of a Schottky diode. Since gate electrode G has a higher potential than source electrode S, the Schottky diode is inversely polarized or blocked. Because of that, a leakage current flows exclusively between the gate and the source.

Since the work function between the p-silicon and the n+ polysilicon rises with the doping of the p-silicon region, the doping of the p-silicon region is preferably selected to be low or weak in the vicinity of gate electrode G. However, at an increasing distance from gate electrode G, the p-doping increases, since the leakage current increases nearly proportionally to the doping, and with that the space charge region does not occupy the whole p-silicon region between the n+ source region and the p-silicon region. The leakage current can be set in the desired manner by the selection of such a doping profile.

Above, the present invention was described in light of enhancement MOSFET's of the n-type. However, it can also be used when enhancement MOSFET's of the p-type are present, in which the discharge of the gate electrode takes place via drain electrode D. If depletion MOSFET's are present, one has to take care, by a suitable negative or positive voltage, that the MOSFET blocks securely.

FIG. 4 shows a diagram to illustrate the doping of the p-type area shown in FIG. 3, as a function of the distance from the gate electrode. From this figure it may be seen that the p-doping increases with increasing distance from the gate electrode, this increase occurring in a linear manner.

One preferred application area of the present invention is in the automotive field. In an automotive application, for example, using a control unit, a power output stage is activated which has one or more MOSFET's. The control unit may be a fan motor control unit. However, the subject matter of the present invention can also be used advantageously in connection with other control units that switch large currents.

1-7. (canceled)

8. A field-effect transistor comprising:
a substrate;
a source electrode;
a drain electrode;
a gate electrode; and
a connection between the gate electrode and at least one of (a) the source electrode, (b) the drain electrode and (c) the substrate, the connection carrying a leakage current.

9. The field-effect transistor according to claim 8, wherein the connection is a silicon dioxide layer into which ions are implanted to form a high-ohmic current path.

10. The field-effect transistor according to claim 8, wherein the connection has a high-ohmic ohmic resistor.

11. The field-effect transistor according to claim 8, wherein the connection is a Schottky diode.

12. The field-effect transistor according to claim 11, further comprising a p-silicon block situated between the gate electrode and the source electrode.

13. The field-effect transistor according to claim 12, wherein a p-doping of the p-silicon block increases with increasing distance from the gate electrode.

14. The field-effect transistor according to claim 13, wherein the p-doping of the p-silicon block increases with increasing distance from the gate electrode in a linear manner.
